(19) United States
(12) Patent Application Publication
(10) Pub. No.: US 2009/0001875 A1
(43) Pub. Date: Jan. 1, 2009

(54) ORGANIC LIGHT-EMITTING DEVICE INCORPORATING MULTIFUNCTIONAL OSMIUM COMPLEXES

(76) Inventors: Yun Chi, Hsinchu (TW); Chung-Chih Wu, Taipei (TW); Chih-Hao Chang, Taipei (TW)

Correspondence Address: RABIN & Berdo, PC, 1101 14TH STREET, NW, SUITE 500, WASHINGTON, DC, 20005, US

(21) Appl. No.: 11/771,011

(22) Filed: Jun. 29, 2007

(51) Int. Cl. H01L 51/52

(52) U.S. Cl. 313/504

(57) ABSTRACT

Fabrication of organic light-emitting devices is disclosed by employing the efficient, multifunctional orange-red emitting osmium complex in combination with a second phosphorescent complex showing strong emission at the shorter wavelength region such as blue or blue-green emitting iridium (Ir) complex. The present invention provides WOLEDs with forward viewing efficiencies up to (17% photon/electron, 35.6 cd/A, 28 lm/W) and total peak external efficiencies up to (28.8%, 47.5 lm/W), giving the conceptual design for the highly efficient and color-stable phosphorescent WOLEDs.

### FIELD OF THE INVENTION

The invention relates to a light-emitting device. More particularly, the invention relates to an organic light-emitting device incorporating multifunctional osmium complexes.

### BACKGROUND

As performances of white organic light-emitting devices (WOLEDs) continue to improve, their use in a variety of applications, such as displays and lighting, becomes increasingly attractive. Full-color OLED displays incorporating high-efficiency WOLEDs with color filters can circumvent issues of high-resolution shadow masking for fine patterning the organic thin films, making it more feasible for fabrication of large-area OLED displays. Being structurally simpler and lightweight, WOLEDs are also an attractive alternative for backlights of liquid crystal displays. Furthermore, with continuously improved efficiencies, WOLEDs are promising for solid-state lighting.

With intrinsically high efficiencies of organic triplet emitters, WOLEDs incorporating phosphorescent emitters are most promising to meet the stringent efficiency requirements in all these applications. Although nearly 100% intrinsic efficiencies have been reported for monochromatic phosphorescent OLEDs, the external quantum efficiencies (along the forward viewing directions) of most phosphor-incorporated WOLEDs reported to date are only up to 10˜12%, which represents an internal quantum efficiency of only 50˜60% in the device when considering the optical out-coupling efficiency of ˜20% in planar OLED structures.

Thus, for phosphor-incorporated WOLEDs, there is still substantial demand in further raising the device efficiencies through engineering device structures and developing better materials or combinations of materials.

### SUMMARY

Accordingly, the disclosure teaches an organic light-emitting device (OLED) incorporating multifunctional osmium complexes that has excellent luminance, light-emitting efficiency and color stability. Highly efficient and color-stable phosphorescent OLEDs are achieved by employing an osmium (Os) complex in combination with another phosphorescent complex showing emission at the shorter wavelength region.

The organic light-emitting devices, which incorporate multifunctional Os complexes. These Os complex can provide the multiple functions such as (i) orange-red emissive dopant in emitting layer; (ii) hole trapping in emitting layer and hole transport layer (HTL); and (iii) acceptor for high energy exciton diffusing from the emitting layer in HTL. The devices comprise a pair of electrodes, at least one electron-transport layer, at least one hole-transport layer, and at least one emitting layer. The electron-transport and hole-transport layers are disposed between the pair of electrodes, and the emitting layer is disposed between the hole-transport layer and the electron-transport layer. Furthermore, at least one of the emitting layers is doped with a phosphorescent complex showing emission at a shorter wavelength region, such as blue or blue-green emission, and either at least one of the hole-transport layer(s) or at least one of the emitting layer(s) or both a hole-transport and emitting layer is doped with Os complex. Without wishing to be bound by hypothesis, doping the Os complex into either a hole-transport layer or an emitting layer appears to improve the balance between hole and electron injection/transport into the emitting layer, thus largely enhancing the EL (electroluminescence) efficiency of monochromatic or white organic light-emitting device.

Using an orange-emitting Os complex in combination with a phosphorescent complex showing strong emission at the shorter wavelength region such as an efficient blue or blue-green emitting iridium (Ir) complex, WOLEDs are provided with forward viewing efficiencies up to (17% photon/electron, 36 cd/A, 28 lm/W) and total external efficiencies up to (28.8%, 47.5 lm/W), and with improved color stability.

Optionally, there can be an electron-injection layer located between the electron-transport layer and the electrode. An electron-injection layer typically enhances the efficiency of electron transport of the organic light-emitting device.

### BRIEF DESCRIPTION OF THE DRAWINGS

FIG. 1A presents a structural diagram of exemplary Os complexes.

FIG. 1B presents a structural diagram of some Ir complexes.

FIG. 2 is a schematic diagram of sample organic light-emitting devices: A1, B1, C1, C1a, C1b and D1.

FIG. 3A shows the normalized EL spectra of Device A1 at different brightness levels.

FIG. 3B shows the external quantum efficiency/power efficiency (in the forward viewing direction) versus current density for Device A1.

FIG. 3C shows the I-V-L characteristics of Device A1.

FIG. 3D shows the CIE coordinates of Device A1 at different brightness levels.

FIG. 4A shows the normalized EL spectra of Device B1 (at 10000 cd/m²) and C1 (at 100 cd/m² and 10000 cd/m²) at different brightness levels.

FIG. 4B shows the external efficiency (in the forward viewing direction) versus current density for Device B1 and C1.

FIG. 4C shows the CIE coordinates at different brightness levels for Device B1 (at 10000 cd/m²) and C1 (at 100 and 10000 cd/m²).

FIG. 5A shows the normalized EL spectra of Device B1, C1a and C1b (at 10000 cd/m²).

FIG. 5B shows the external efficiency (in the forward viewing direction) versus current density for Device B1, C1a and C1b.

FIG. 5C shows the CIE coordinates for Device B1, C1a and C1b (at 10000 cd/m²).

FIG. 6A shows the normalized EL spectra of Device D1 at different brightness levels.

FIG. 6B shows the external quantum efficiency/power efficiency characteristics (in the forward viewing direction) versus current density for Device D1.

FIG. 6C shows the I-V-L characteristics of Device D1.

FIG. 6D shows the CIE coordinates of Device D1 at different brightness levels.

FIG. 7 is a schematic diagram showing device structures of organic light-emitting devices: A2, B2, C2 and D2.

FIG. 8A shows the normalized EL spectra of Device A2 at different brightness levels.

FIG. 8B shows the external quantum efficiency/power efficiency (in the forward viewing direction) versus current density for Device A2.

FIG. 8C shows the I-V-L characteristics of Device A2.

FIG. 8D shows the CIE coordinates of Device A2 at different brightness levels.

FIG. 9A shows the normalized EL spectra of Device B2 (at 10000 cd/m²) and C2 (at 100 cd/m² and 10000 cd/m²) at different brightness levels.

FIG. 9B shows the external efficiency (in the forward viewing direction) versus current density for Device B2 and C2.

FIG. 9C shows the CIE coordinates for Device B2 (at 10000 cd/m²) and C2 (at 100 and 10000 cd/m²).

FIG. 10A shows the normalized EL spectra of Device D2 at different brightness levels.

FIG. 10B shows the external quantum efficiency/power efficiency characteristics (in the forward viewing direction) versus current density for Device D2.

FIG. 10C shows the I-V-L characteristics of Device D2.

FIG. 10D shows the CIE coordinates of Device D2 at different brightness levels.

FIG. 11 is a schematic diagram showing device structures of organic light-emitting devices A3, B3, C3 and D3.

FIG. 12A shows the normalized EL spectra of Device A3 at different brightness levels.

FIG. 12B shows the external quantum efficiency/power efficiency (in the forward viewing direction) versus current density for Device A3.

FIG. 12C shows the I-V-L characteristics of Device A3.

FIG. 12D shows the CIE coordinates of Device A3 at different brightness levels.

FIG. 13A shows the normalized EL spectra of Device B3 (at 10000 cd/m²) and C3 (at 100 cd/m² and 10000 cd/m²) at different brightness levels.

FIG. 13B shows the external efficiency (in the forward viewing direction) versus current density for Device B3 and C3.

FIG. 13C shows the CIE coordinates for Device B3 (at 10000 cd/m²) and C3 (at 100 cd/m² and 10000 cd/m²).

FIG. 14A shows the normalized EL spectra of Device D3 at different brightness levels.

FIG. 14B shows the external quantum efficiency/power efficiency characteristics (in the forward viewing direction) versus current density for Device D3.

FIG. 14C shows the I-V-L characteristics of Device D3.

FIG. 14D shows the CIE coordinates of Device D3 at different brightness levels.

### DETAILED DESCRIPTION

Taught herein is an organic light-emitting device comprising a multifunctional Os complex, which comprises a pair of electrodes, at least one electron-transport layer, at least one hole-transport layer, and at least one emitting layer. The electron-transport and hole-transport layer are disposed between the pair of electrodes, and the emitting layer is disposed between the hole-transport layer and the electron-transport layer. At least one of the emitting layers, when there are multiple emitting layers, is doped with a second phosphorescent complex having strong emission at a shorter wavelength region, and either one or more hole-transport layers or one or more emitting layers or both one or more hole-transport and one or more emitting layers are doped with Os complex.

In practice, OLEDs that have both a hole-transport and emitting layer doped with an Os complex, the concentration of the Os complex in the emitting layer is maintained at a relatively lower level, for which the dopant concentration ranges from 0.01 wt. % to 0.5 wt. %. Its major function is presumably to suppress orange emission generated from the white emitting layer at the conditions using lower applied biases. On the other hand, when both the hole-transport layer and the emitting layer are doped with Os complex, the concentration of the Os complex in the hole-transport layer is maintained at a relatively higher level, for which the typical concentration ranges from 0.5 wt. % to 10 wt. %. This measure is presumably to enhance the orange emission from Os complex and suppressing the blue-shift caused by the emission from green, blue-green or blue-emitting phosphorescent metal complex at the higher applied biases. By application of both measures, the variation of EL spectra versus biases is substantially reduced and the stability of color chromaticity is improved.

In other versions, the OLED further comprises an electron-injection layer that is located between the electron-transport layer and the electrode. The electron-injection layer is optional but could improve the device efficiency. The electron-injection layer comprises a thin layer of alkali metal salt and metal such as LiF and aluminum; other suitable alkali metal salt and alkaline metals are: Cs₂CO₃, CsF, CsNO₃, lithium, and cesium metal, respectively.

### A. Emitters

As described herein, the white-light OLED devices comprise at least two emitters, one that emits in the range from about 580 nm to about 630 nm (orange to red spectrum), and a second that emits in the range from about 450 nm to about 500 nm (blue to blue-green spectrum).

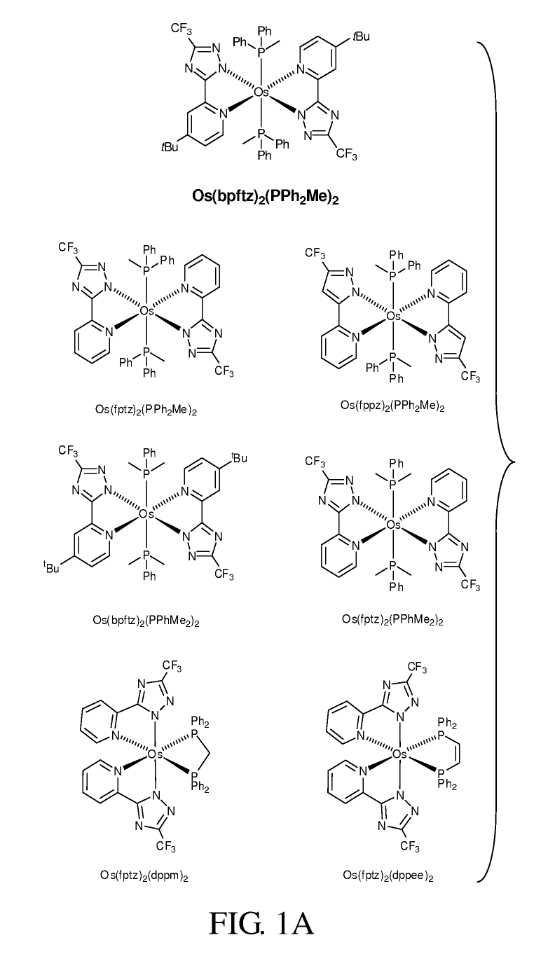

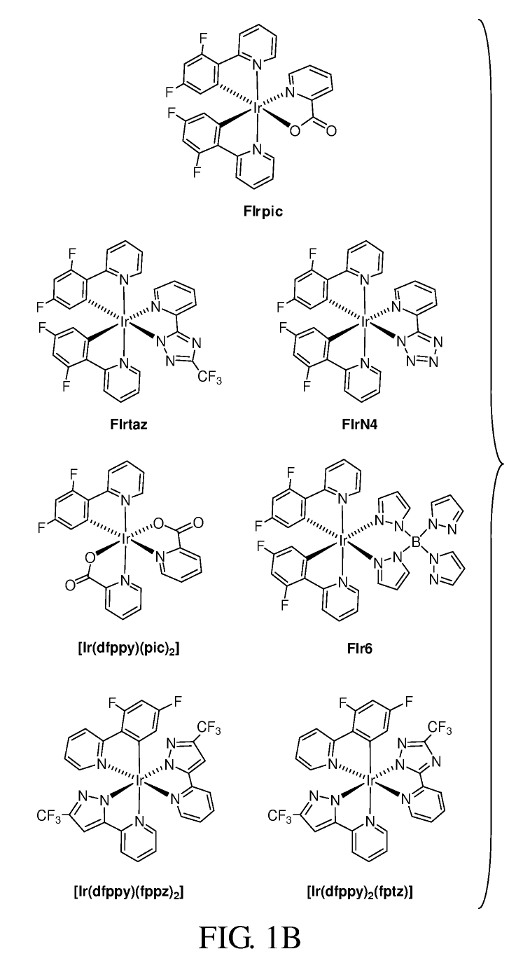

Orange and red emitters are triplet-based emitters and can be based on osmium, iridium, and platinum complexes that emit in the range from about 580 nm to about 630 nm (orange to red). The Os complex typically possesses high HOMO (Highest Occupied Molecular Orbital) energy level. FIG. 1A presents structures of some emissive Os complexes; namely: Os(bpftz)₂(PPh₂Me)₂, Os(bpftz)₂(PPh₂Me)₂, Os(fptz)₂(PPh₂Me)₂, Os(fppz)₂(PPh₂Me)₂, Os(bpftz)₂(PPhMe₂)₂, Os(fptz)₂(PPhMe₂)₂, Os(fptz)₂(dppm)₂ and Os(fptz)₂(dppee)₂. In addition, the Os complex may be substituted by other phosphorescent metal complexes possessing similar orange or red emission in the range 580˜630 nm and with relatively higher HOMO energy level. These examples are provided as non-limiting examples, and other Os and/or transition metal complexes exhibiting similar orange to red luminescence, high HOMO energy level, improved emission quantum yields and chemical and thermal stability may be employed.

Moreover, the present invention had shown that the unique multifunctionality of orange-red emitting phosphorescent Os complex is highly useful for achieving excellent internal and external efficiencies of OLEDs. This is not only due to high emission efficiency of the Os complex, but also due to its effective hole trapping capability, which is beneficial to and useful for balancing hole/electron transport when doped or introduced at appropriate locations of the device. In practice, the present invention clearly provides that doping the Os complex into either the hole-transport layer TCTA or the mCP host layer has improved the balance between hole and electron injection/transport into the emitting layer mCP:FIrpic, thus enhancing the overall EL efficiency.

On the other hand, the second phosphorescent complex, which shows strong emission at a shorter wavelength region, can be blue or blue-green emitting phosphorescent metal complexes. For example, these blue or blue-green emitting complexes can be Ir complexes. FIG. 1B depicts the structural diagram of some Ir complexes that emit in the shorter wavelength region, providing the blue to blue-green emission of the white light spectral region. The depicted Ir complexes are FIrpic, FIrtaz, FIrN4, [Ir(dfppy)(pic)₂], FIr6, [Ir(dfppy)(fppz)₂] and [Ir(dfppy)₂(fptz)]. Additionally, these examples are provided as non-limiting examples, and other Ir and/or transition metal complexes exhibiting similar blue or blue-green luminescence, improved emission quantum yields and chemical and thermal stability may be employed.

### B. Host Materials

The emitter layer comprises a host material. The host material may be selected to have a wide energy gap. Example of host materials includes 1,3-bis(9-carbazolyl)benzene (mCP), 1,3,5-Tris(carbazol-9-yl)benzene (TCP), p-bis(triphenylsilyly)benzene (UGH2), 1,3-Bis(triphenylsilyl)benzene (UGH3), 3,5-bis(9-carbazolyl)tetraphenylsilane (SimCP), and 9-(4-tertbutylphenyl)-3,6-bis(tri-phenylsilyl)-9H-carbazole (CzSi), 4,4′-Bis(9-carbazolyl)-2,2′-dimethyl-biphenyl (CDBP), 2,2′,7,7′-Tetrakis(carbazol-9-yl)-9,9′-spiro-bifluorene (spiro-CBP) etc. In the preferred embodiments, the emitting layer comprises the wide-gap host materials p-bis(triphenylsilyly)benzene (UGH2) and 9-(4-tertbutylphenyl)-3,6-bis(tri-phenylsilyl)-9H-carbazole (CzSi).

### C. Electron Transporting Materials

This layer of material is used to transport electrons into the emissive layer comprising the host material and the emissive material. The electron transporting materials may be an electron transporting matrix selected from group of metal quinoxolates, oxadiazoles and triazoles. The example of electron transporting materials are 3-(4-biphenylyl)-4-phenyl-5-(4-tert-butylphenyl)-1,2,4-triazole (TAZ), 2,2′,2″-(1,3,5-Benzinetriyl)-tris(1-phenyl-1-H-benzimidazole) (TPBi), 2-(4-Biphenylyl)-5-(4-tert-butylphenyl)-1,3,4-oxadiazole (PBD), 2,9-Dimethyl-4,7-diphenyl-1,10-phenanhroline (BCP), 4,7-Diphenyl-1,10-phenanthroline (BPhen), Bis-(2-methyl-8-quinolinolate)-4-(phenylphenolato)aluminium (BAlq), 1,3-Bis[2-(2,2′-bipyridine-6-yl)-1,3,4-oxadiazo-5-yl]benzene (Bpy-OXD), 1,3-Bis[5-(4-tert-butylphenyl)-1,3,4-oxadiazole-2-yl]benzene) (OXD-7) etc.

### D. Hole Transporting Materials

This layer of material is used to transport holes into the emissive layer comprising the host material and the emissive material. The example of hole transporting materials are 4,4′-bis[N-(1-naphthyl)-N-phenyl-amino]biphenyl (α-NPD), 4,4′,4″-tris(carbazole-9-yl)-triphenylamine (TCTA), 4,4′,4″-Tris(N,N-diphenyl-amino)triphenylamine (NATA), 4,4′,4″-Tris(N-3-methylphenyl-N-phenyl-amino)triphenylamine (m-MTDATA), N,N,N′,N′-tetrakis(4-methoxy-phenyl)benzidine (MeO-TPD), N,N′-Bis(3-methylphenyl)-N,N′-bis(phenyl)-benzidine (TPD), 2,2′,7,7′-Tetrakis(m,n-diphenylamino)-9,9′-spirobifluorene (spiro-TAD), 9,9-Bis[4-(N,N-bis-biphenyl-4-yl-amino)phenyl]-9H-fluorene (BPAPF) etc.

### E. Electrodes

Electrodes, which include both an anode and a cathode, may be any suitable conducting material that provides desirable properties. Anode may be any electrode that is sufficiently conductive to transport holes to the organic layers, and preferably has a work function higher than 4 eV, i.e. being a high work function material. Preferred anode include conductive metal oxides, such as indium tin oxide (ITO) and indium zinc oxide (IZO), aluminum zinc oxide (AlZnO) and metal elements. It should also be sufficiently transparent to create a bottom-emitting device. Anode may be opaque and/or reflective, while reflective anode may be suitable for top-emitting WOLED, for increasing the amount of light emitted from the top of WOLED. Other anode materials may be utilized.

On the other hand, the cathode may be any suitable materials, compound structure or even composites known to the art, as long as it is capable of conducting electrons and allowing an effective injection of electron into the adjacent organic layer of an WOLED. The cathode is preferably made of a material having a low work function of below 4 eV. This cathode may be transparent, opaque or reflective. The preferred cathode materials include a thick layer of metal alloys such as magnesium and silver, or aluminum deposited with an underlying thin layer of LiE Depending on their specific requirement and device architecture, other cathode materials may be used to improve the electron injection properties of the electrode.

### EXAMPLES

### Example 1

### Construction and Testing of Six OLED Devices

OLEDs were fabricated on the ITO-coated glass substrates with multiple organic layers sandwiched between the transparent bottom indium-tin-oxide (ITO) anode and the top metal cathode. The organic and metal layers were deposited by vacuum evaporation in a vacuum chamber with a base pressure of ≦10⁻⁶ torr. The deposition system permits the fabrication of the complete device structure in a single pump-down without breaking vacuum. The deposition rate of organic layers was kept at ˜0.2 nm/s. The active area of the device is 2×2 mm², as defined by the shadow mask for cathode deposition.

Current-voltage-brightness (I-V-L) characterization of the devices was performed with a source-measurement unit (SMU) and a calibrated Si photodiode. Electroluminescence (EL) spectra of devices were collected by a calibrated CCD spectrograph. Total photon output from the device (either from the viewing direction or from all surfaces of the device) was measured in an integrating sphere containing a calibrated photodiode.

The blue phosphorescent iridium complex bis[(4,6-difluorophenyl)-pyridinato-N,C2](picolinato)Ir(III) (FIrpic) and the red phosphorescent osmium complex Os(bpftz)₂(PPh₂Me)₂ [where bpftz stands for 3-trifluoromethyl-5-(4-tert-butyl-2-pyridyl)triazolate, PPh₂Me represents a typical monodentate phosphine ligand] as shown in FIGS. 1A and 1B were employed in the preparation of WOLEDs. The widely used blue phosphorescent emitter, FIrpic, exhibits very high photoluminescence (PL) quantum efficiency (>90%) in wide-gap hosts. On the other hand, the osmium complex Os(bpftz)₂(PPh₂Me)₂ with high steric hindrance shows orange emission around 603 nm, short excited-state lifetime (0.97 μs) and high PL quantum yield of ˜90% in solution. The related osmium complexes had been used to fabricate highly efficient orange to red phosphorescent OLEDs with external quantum efficiencies approaching 20%. Thus both of these iridium and osmium triplet emitters are intrinsically very efficient.

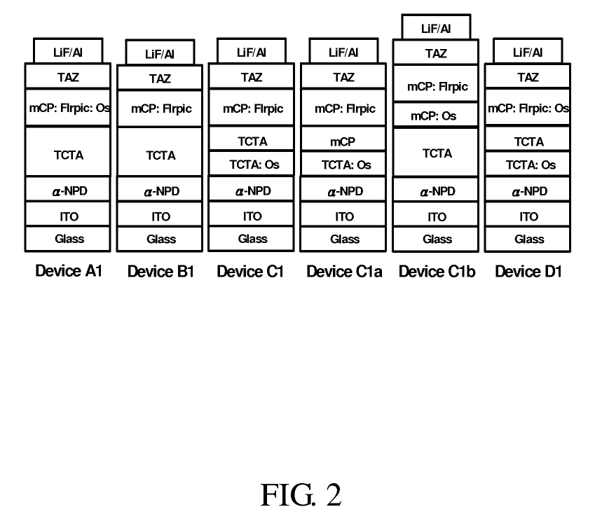

FIG. 2 depicts the schematic diagram illustrating the organic light-emitting device A1, B1, C1, C1a, C1b and D1. As shown in FIG. 2, Device A (WOLED) involves co-doping both emitters into the wide-gap host 1,3-bis(9-carbazolyl)benzene (mCP) as the emitting layer (EML). More specifically, the structure of Device A1 is: Glass/ITO/α-NPD (30 nm)/TCTA (30 nm)/mCP: FIrpic 8 wt. %: Os(bpftz)₂(PPh₂Me)₂ 0.5 wt. % (15 nm)/TAZ (50 nm)/LiF (0.5 nm)/Al (150 nm), where α-NPD and TCTA are used as the hole-transport layers (HTLs), TAZ as the electron-transport layer (ETL), and LiF as the electron-injection layer.

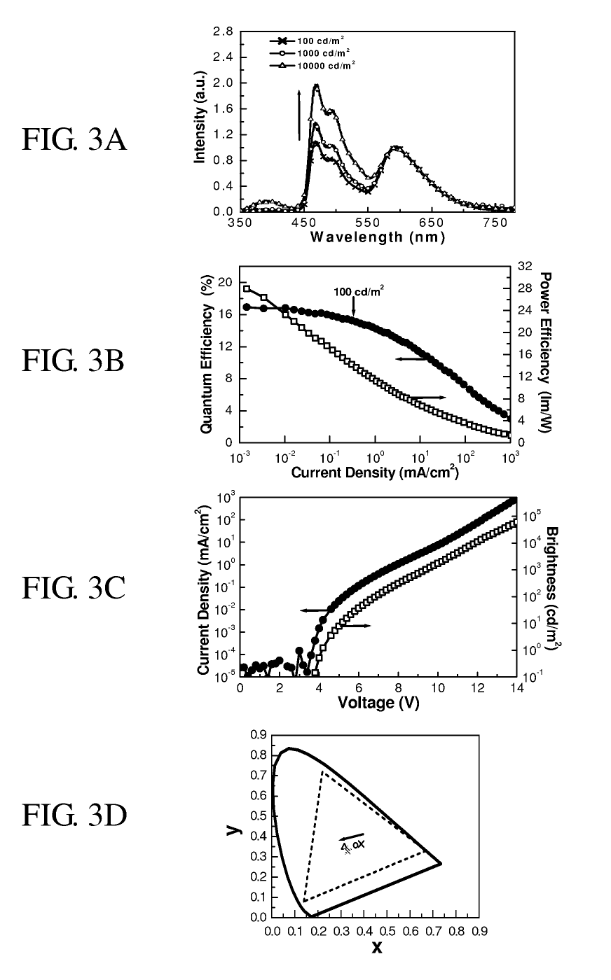

FIG. 3A shows the normalized EL spectra of Device A1 at different brightness levels. The EL spectra (normalized at the emission peak of the Os complex) show contributions from both blue emission of FIrpic and orange emission of Os complex Os(bpftz)₂(PPh₂Me)₂, giving a virtually white emission. FIG. 3B shows the external quantum efficiency/power efficiency (in the forward viewing direction) versus current density of Device A1 and FIG. 3C shows the I-V-L characteristics of Device A1. FIG. 3D shows the CIE coordinates of Device A1 at different brightness levels. The summarized data of efficiency characteristics, the I-V-L characteristics and etc. of Device A1, B1, C1, C1a, C1b and D1 are shown in Table 1.

Table 1 is the summary of devices characteristics in example 1.

TABLE 1

| | | | Max. | |
|---|---|---|---|---|
| | | | Total | |
| | Max. | Efficiencies | effi- | CIE |
| | Efficiencies | (at 100 cd/m²) | ciencies | coordinates |
| | [%, cd/A, | [%, cd/A, | [%, | (at 10², |
| Device | lm/W] | lm/W] | lm/W] | 10⁴ cd/m²) |
| A1 | 17.0, 35.6, 28.0 | 15.1, 30.4, 13.6 | 28.8, | (0.388, 0.363), |
| | | | 47.5 | (0.315, 0.348) |
| B1 | 4.8, 10.2, 6.1 | 4.4, 9.3, 4.9 | — | (0.170, 0.356), |
| | | | | (0.172, 0.355) |
| C1 | 11.7, 25.7, 12.6 | 11.7, 25.6, | — | (0.178, 0.359), |
| | | | 11.8 | (0.208, 0.366) |
| C1a | 14.0, 28.7, 16.8 | 13.6, 27.9, 12.2 | — | (0.205, 0.344), |
| | | | | (0.220, 0.344) |
| C1b | 14.0, 28.7, 17.2 | 13.2, 27.3, 11.9 | — | (0.197, 0.344), |
| | | | | (0.191, 0.339) |
| D1 | 14.9, 29.3, 17.8 | 13.1, 25.9, 8.9 | 25.4, | (0.334, 0.362), |
| | | | 35.3 | (0.311, 0.356) |

Device A1 exhibits a turn-on voltage of ˜3.5 V Most impressively, Device A1 shows peak efficiencies of 17% photon/electron, 35.6 cd/A, and 28 lm/W for the forward viewing directions. Such high quantum efficiency implies a high internal quantum efficiency of nearly 90% in Device A1. At the practical brightness of 100 cd/m², the forward viewing efficiencies remain high around 15.1%, 30.4 cd/A, and 13.6 lm/W. For lighting applications, the light emitted from all surfaces of the substrate can in principle be redirected to the forward direction by some lighting fixtures. The total efficiencies (quantum efficiency and power efficiency) of the device were also characterized using an integrating sphere setup. The total quantum and power efficiencies measured in the sphere were about 1.7 times larger than the forward viewing efficiencies, consistent with previous reports. As such, Device A1 indeed has a total peak external quantum efficiency and a total power efficiency of 28.8% and 47.5 lm/W, respectively.

The high quantum efficiencies of the white organic light-emitting Device A1 is rather remarkable, since the control blue-emitting device with a structure similar to Device A1 exhibited substantially lower efficiencies. This control blue-emitting OLED (Device B1 showed in FIG. 2) has the structure of: ITO/α-NPD (30 nm)/TCTA (30 nm)/mCP: FIrpic 8 wt. % (15 nm)/TAZ (50 nm)/LiF (0.5 nm)/Al (150 nm), which is nearly same as that of Device A1, except for no Os complex co-doped into the mCP host.

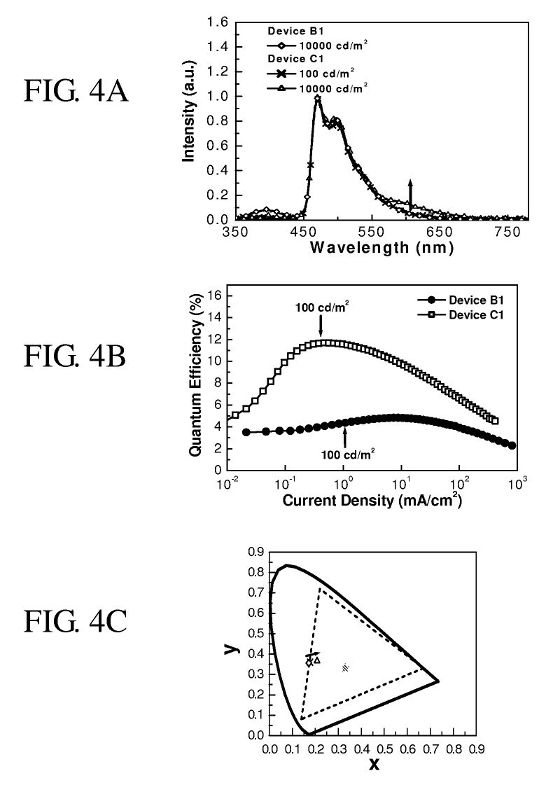

FIG. 4A shows the normalized EL spectra of Device B1 (at 10000 cd/m²) and C1 (at 100 cd/m² and 10000 cd/m²). FIG. 4B shows the external quantum efficiency (in the forward viewing direction) versus current density for Device B1 and C1. FIG. 4C shows the CIE coordinates at different brightness levels for Device B1 and C1. Such a blue-emitting device B1 gave a substantially lower peak external quantum efficiency of ˜4.8% (in the forward viewing directions, FIG. 4B and Table 1). In contrast, with co-doping a smaller amount of the Os complex Os(bpftz)₂(PPh₂Me)₂ in the emitting layer (i.e. Device A1), the quantum efficiency of the whole system is nearly tripled, indicating that the Os complex has additional critical functionalities other than just serving as an energy acceptor for the blue emitter FIrpic.

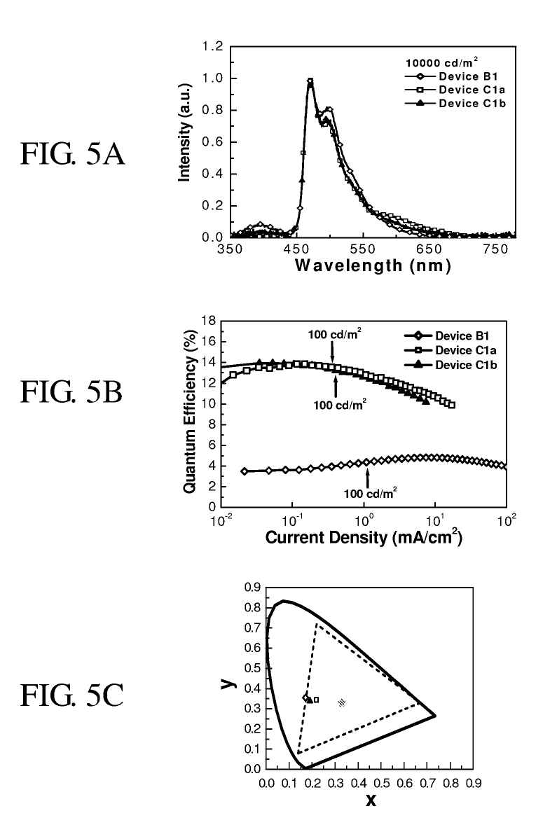

To investigate the role of the Os complex, a third testing device structure (Device C1 showed in FIG. 2) with the Os complex doped into a portion (25 nm) of the hole-transport layer TCTA was then fabricated and characterized. This device C1 has the structure of: Glass/ITO/α-NPD (30 nm)/TCTA: Os(bpftz)₂(PPh₂Me)₂ 3.0 wt. % (25 nm)/TCTA (5 nm)/mCP: FIrpic 8 wt. % (15 nm)/TAZ (50 nm)/LiF (0.5 nm)/Al (150 nm). As shown in FIG. 4 A, EL from Device C1 shows dominant blue emission of FIrpic, yet the peak quantum efficiency is now largely raised to 11.7% (25.7 cd/A) as compared to the 4.8% observed for Device B1 (shown in FIG. 4B and Table 1). It is also worth mentioning that by replacing the 5-nm non-doped TCTA buffer in Device C1 with the higher-energy-gap mCP (i.e. Device C1a, FIG. 2), the efficiency of the blue OLED can be further increased to 14% due to better confinement of high-energy triplet excitons (shown in FIG. 5B and Table 1). Device C1a has the structure of: Glass/ITO/α-NPD (30 nm)/TCTA: Os(bpftz)₂(PPh₂Me)₂ 3.0 wt. % (25 nm)/mCP (5 nm)/mCP: FIrpic 8 wt. % (15 nm)/TAZ (50 nm)/LiF (0.5 nm)/Al (150 nm).

Device C1b is also fabricated to further verify the role of the Os complex in this system. In device C1b, the Os-complex-doped mCP layer is inserted between the hole-transport layer (TCTA) and blue-emitting layer (mCP: FIrpic). The structure of device C1b is: Glass/ITO/α-NPD (30 nm)/TCTA (30 nm)/mCP: Os(bpftz)₂(PPh₂Me)₂ 1.0 wt. % (10 nm)/mCP: FIrpic 8 wt. % (15 nm)/TAZ (50 nm)/LiF (0.5 nm)/Al (150 nm). The EL from Device C1b still shows dominant blue emission of FIrpic even at high current densities (shown in FIG. 5A, Table 1, and FIG. 5C). It indicates that the Os complex mainly serves as the hole-trapping dopant when it is doped on the hole-transport side and its doping area does not overlap with the exciton formation zone (the mCP:FIrpic layer). Similar to Device C1a, the peak quantum efficiency of Device C1b is also raised to 14% (28.7 cd/A), compared to those of Device B1 (shown in FIG. 5B and Table 1).

The data of Devices A1, B1, and C1 clearly suggest that doping the Os complex into either the hole-transport layer TCTA or the mCP host layer has improved the balance between hole and electron injection/transport into the emitting layer mCP:FIrpic, thus enhancing the EL efficiency. Electrochemical data of these related Os complexes shows that they in general possess low oxidation potentials (and thus higher HOMO (Highest Occupied Molecular Orbital) levels and lower ionization potential). The ionization potential of the present Os complex estimated from the oxidation potential is about 4.8 eV, which is substantially lower than those of TCTA, mCP and FIrpic (all of 5.5˜6.0 eV). In view of such an energy-level relationship, it is well expected that the Os complex could function as effective hole traps in both Devices A1 and C1, retarding hole transport and reducing excessive hole injection into the emitting layer. This hole trapping also reduces excessive hole injection into the electron-transport layer since the UV emission from the ETL TAZ is generally reduced with the Os complex doping. The accumulation of trapped holes may also help to establish a stronger electric field for enhancing electron injection into the emitting layer. Overall, all these factors contribute together to better balance of the carrier transport for both carriers and the efficiency enhancement.

Although the efficiencies of Device A1 are impressive, it shows a color shift upon increase of the bias/brightness (shown in FIG. 3A and FIG. 3D). Blue emission from FIrpic grows relative to the emission of Os(bpftz)₂(PPh₂Me)₂ at higher current densities, causing the 1931 CIE coordinates to blue-shift from (0.388 0.363) to (0.315, 0.348) at the brightness of 100-10000 cd/m². This may be due to the saturation of the lightly doped orange-red osmium phosphor, leading to reduction the efficiency of energy transfer from FIrpic to the Os complex at higher excitation densities. This issue may be mitigated (and the color stability of the WOLED may be improved) by creating another channel in the device for the high-energy excitons to be still appropriately relaxed or transferred to the lower-energy excited states of Os complexes even at high excitation densities. In Device C1, the contribution of the Os emission (although smaller) increases with the brightness (shown in FIG. 4C), contrary to the case of Device A1. Such a characteristic suggests that in Device C1, at higher bias/brightness, either the carrier recombination zone shifts closer to the TCTA:Os(bpftz)₂(PPh₂Me)₂ layer (i.e. the hole-transport layer) or a portion of the high-energy excitons in the mCP:FIrpic layer (i.e. the emitting layer) migrates to the TCTA:Os(bpftz)₂(PPh₂Me)₂ layer (which is possible because the triplet energy of the 5-nm buffer TCTA is lower than that of FIrpic), giving the increased emission from the Os complex.

The second type of WOLED in the present invention, Device D1 (shown in FIG. 2), was fabricated using the structure of: Glass/ITO/α-NPD (30 nm)/TCTA: Os(bpftz)₂(PPh₂Me)₂ 3.0 wt. % (25 nm)/TCTA (5 nm)/mCP: FIrpic 8 wt. %: Os(bpftz)₂(PPhMe)₂ 0.2 wt. % (15 nm)/TAZ (50 nm)/LiF (0.5 nm)/Al (150 nm). Device D1 simultaneously incorporates an orange-red EML and a white EML. On one hand, the concentration of Os complex in the white EML is decreased to suppress the orange-red emission (from the white EML) and to achieve a more balanced white emission at lower biases. On the other hand, the concentration of the Os complex in the TCTA layer is increased to enhance orange emission from the Os complex at higher biases.

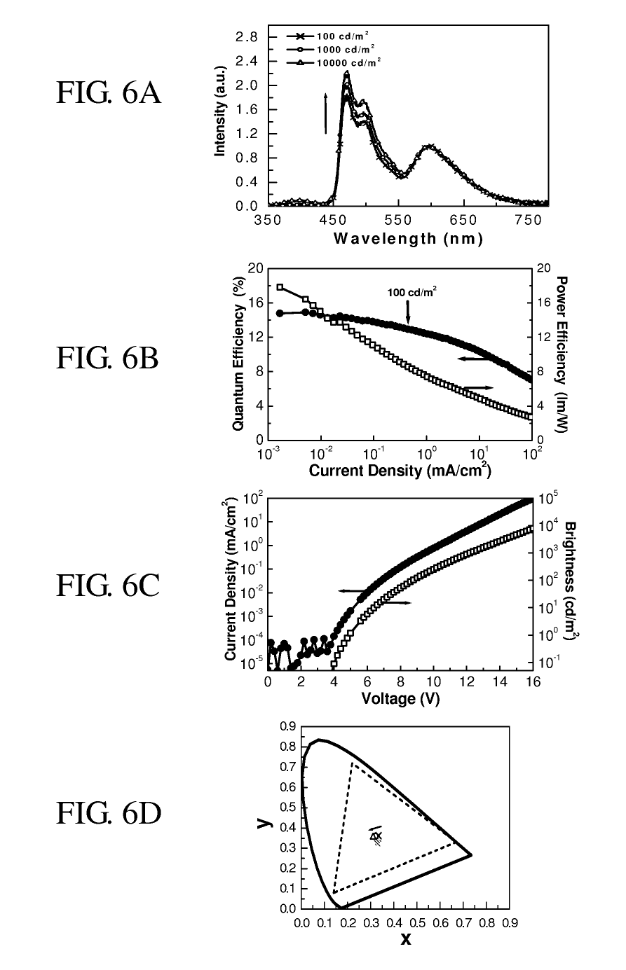

FIG. 6A shows the normalized EL spectra of Device D1 at different brightness levels. FIG. 6D shows the CIE coordinates of Device D1 at different brightness levels. Compared to Device A1, the variation of EL spectra with biases in Device D1 is much reduced. Moreover, as shown in FIG. 6D, for the brightness of 100 cd/m²-10000 cd/m², only a small shift of CIE coordinates from (0.334, 0.362) to (0.311, 0.356) is observed, giving (Δx=−0.023, Δy=−0.006). FIG. 6B shows the external quantum efficiency/power efficiency (in the forward viewing direction) versus current density for Device D1, while FIG. 6C shows the I-V-L characteristics of Device D1. Device D1 has peak efficiencies of 14.9%, 29.3 cd/A, and 17.8 μm/W in the forward viewing direction, corresponding to total peak efficiencies of 25.4% and 30.3 lm/W. At the practical brightness of 100 cd/m², this device D1 exhibits efficiencies of 8.9 lm/W, 13.1%, and 25.9 cd/A in the forward viewing direction.

Furthermore, by placing an emitting/trapping layer involving the Os complex in the proximity of a white-emitting layer that also incorporates the Os complex, the present invention provides a design to the efficient phosphorescent WOLED that would provide the improved stability of color chromaticity versus applied biases or device brightness.

More particularly, the significant color shift with increasing of the bias/brightness may be mitigated (and the color stability of the WOLED may be improved) by creating another channel in the device for the high-energy excitons to be relaxed or transferred to the lower-energy excited states of Os complex even at high excitation densities. Overall, in the present invention, the multifunctionality of the phosphorescent Os complex may be of general use for implementation of highly efficient monochromatic or white phosphorescent OLEDs.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

### Example 2

### Construction and Testing of Four OLED Devices

To further verify the unique multifunction of Os complex, we also tested other series of devices. In example 2, the structures of the devices are the same with those in example 1 expect the thickness of emitting layer. The thickness of emitting layer was increased from 15 nm to 25 nm.

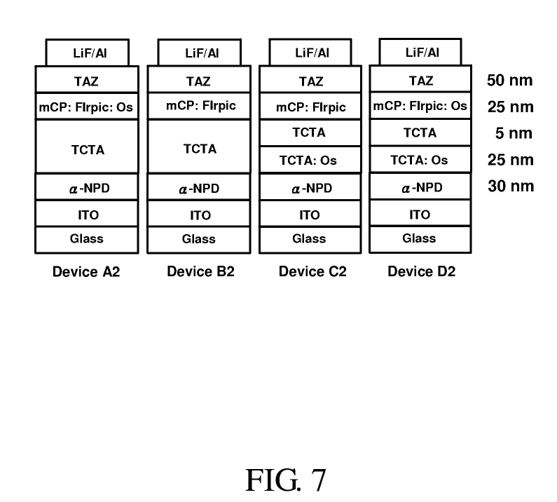

FIG. 7 depicts the schematic device structures of organic light-emitting devices A2, B2, C2 and D2. As shown in FIG. 7, the structure of Device A2 is: Glass/ITO/α-NPD (30 nm)/TCTA (30 nm)/mCP: FIrpic 8 wt. %: Os(bpftz)₂(PPh₂Me)₂ 0.5 wt. % (25 nm)/TAZ (50 nm)/LiF (0.5 nm)/Al (150 nm).

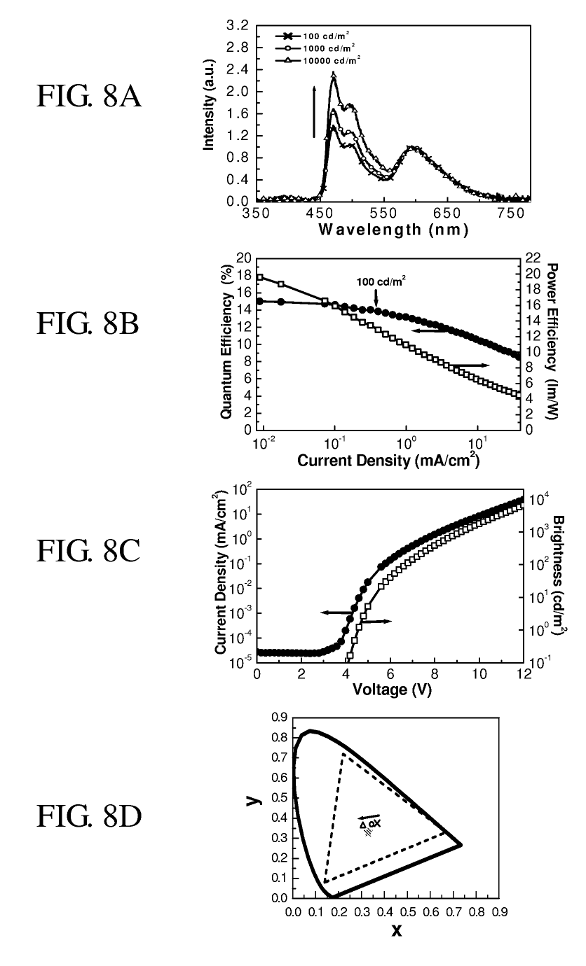

FIG. 8A shows the normalized EL spectra of Device A2 at different brightness levels. The EL spectra still show balanced white emission. FIG. 8B shows the external quantum efficiency/power efficiency (in the forward viewing direction) versus current density of Device A2 and FIG. 8C shows the I-V-L characteristics of Device A2. FIG. 8D shows the CIE coordinates of Device A2 at different brightness levels. The summarized data of efficiency characteristics, the I-V-L characteristics and etc. of Device A2, B2, C2 and D2 are shown in Table 2.

Table 2 is the summary of devices characteristics in example 2.

TABLE 2

| | Max. | Efficiencies | | CIE |
|---|---|---|---|---|
| | Efficiencies | (at 100 cd/m²) | Max. Total | coordinates |
| | [%, cd/A, | [% cd/A, | efficiencies | (at 10², |
| Device | lm/W] | lm/W] | [%, lm/W] | 10⁴ cd/m²) |
| A2 | 15.0, 30.0, | 13.8, 27.8, | 25.5, 34.9 | (0.369, 0.374), |
| | 20.5 | 12.9 | | (0.307, 0.362) |
| B2 | 9.2, 19.0, 8.4 | 9.2, 19.0, 7.4 | — | (0.167, 0.335), |
| | | | | (0.168, 0.337) |
| C2 | 11.9, 25.4, | 11.9, 25.2, | — | (0.181, 0.355), |
| | 12.8 | 10.7 | | (0.193, 0.355) |
| D2 | 14.9, 30.7, | 13.5, 27.9, | 25.3, 37.1 | (0.346, 0.378), |
| | 21.8 | 11.5 | | (0.303, 0.370) |

Device A2 still keeps at high efficiency and exhibits peak efficiencies of 15% photon/electron, 30 cd/A, and 20.5 lm/W for the forward viewing directions. At the practical brightness of 100 cd/m², the forward viewing efficiencies remain high around 13.8%, 27.8 cd/A, and 12.9 lm/W. Furthermore, Device A2 has a total peak external quantum efficiency and a total power efficiency of 25.5% and 34.9 lm/W, respectively.

The control blue-emitting OLED (Device B2 showed in FIG. 7) in example 2 has the structure of: ITO/α-NPD (30 nm)/TCTA (30 nm)/mCP: FIrpic 8 wt. % (25 nm)/TAZ (50 nm)/LiF (0.5 nm)/Al (150 nm), which is nearly same as that of Device A2, except for no Os complex co-doped into the mCP host.

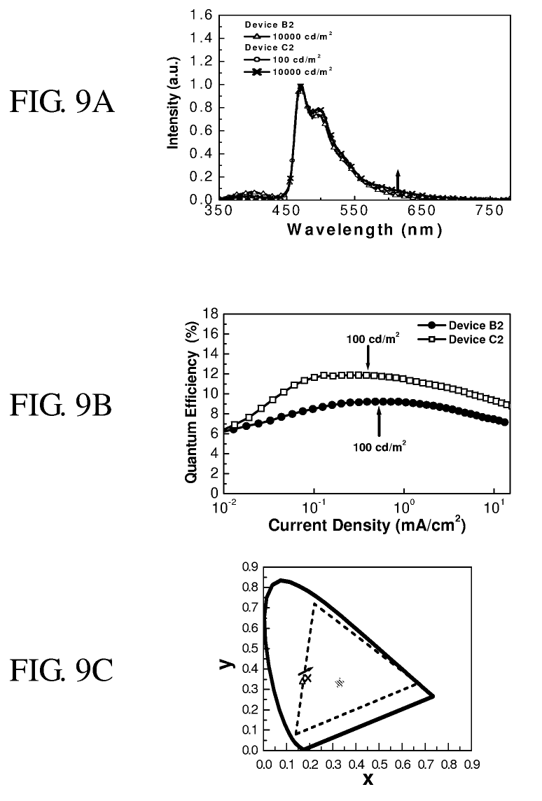

FIG. 9A shows the normalized EL spectra of Device B2 (at 10000 cd/m²) and C2 (at 100 cd/m² and 10000 cd/m²). FIG. 9B shows the external quantum efficiency (in the forward viewing direction) versus current density for Device B2 and C2. FIG. 9C shows the CIE coordinates at different brightness levels for Device B2 (at 10000 cd/m²) and C2 (at 100 cd/m² and 10000 cd/m²). In example 2, the increased thickness of emitting layer modify the condition of carrier balance and thus Device B2 shows higher external quantum efficiency of 9.2% in the forward viewing directions than Device B1. (FIG. 9B and Table 2). However, the efficiency of Device B2 remains lower than the efficiency of Device A2. As in example 1, Device C2 was also fabricated to investigate the role of the Os complex. The Os complex was doped into a portion (25 nm) of the hole-transport layer TCTA. This device C2 has the structure of: Glass/ITO/α-NPD (30 nm)/TCTA: Os(bpftz)₂(PPh₂Me)₂ 3.0 wt. % (25 nm)/TCTA (5 nm)/mCP: FIrpic 8 wt. % (25 nm)/TAZ (50 nm)/LiF (0.5 nm)/Al (150 nm). As shown in FIG. 9 A and FIG. 9C, EL spectra of Device C2 still shows dominant blue emission of FIrpic, yet the peak quantum efficiency is now raised to 11.9% (25.4 cd/A) (shown in FIG. 9B and Table 2). It confirms that the Os complex can reduce the excessive hole-injection into emitting layer and improve the carrier balance.

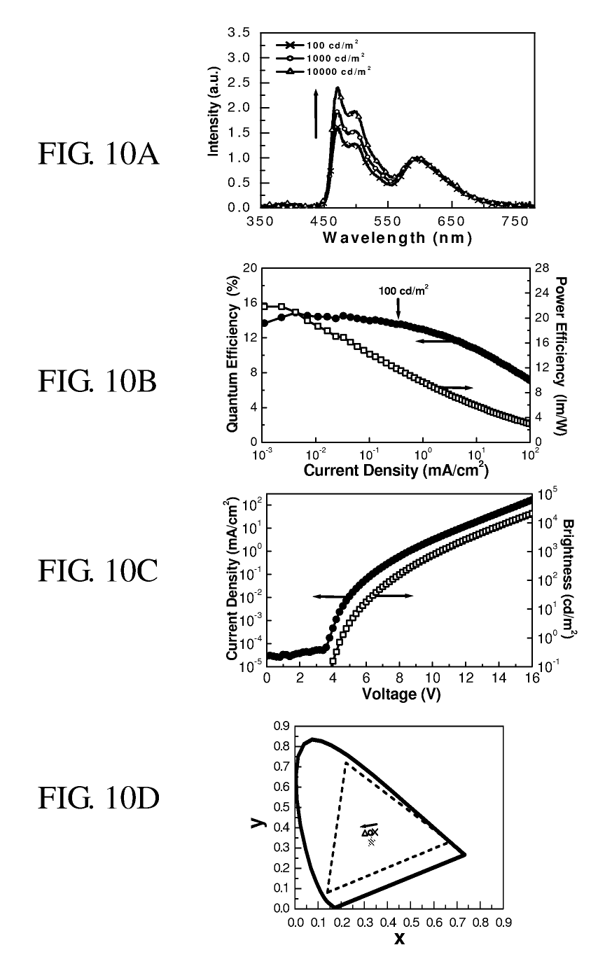

In addition, WOLED with double emitting layers, Device D2 (shown in FIG. 7), was fabricated using the structure of: Glass/ITO/α-NPD (30 nm)/TCTA: Os(bpftz)₂(PPh₂Me)₂ 3.0 wt. % (25 nm)/TCTA (5 nm)/mCP: FIrpic 8 wt. %: Os(bpftz)₂(PPhMe)₂ 0.2 wt. % (25 nm)/TAZ (50 nm)/LiF (0.5 nm)/Al (150 nm). FIGS. 10A and 10D show the normalized EL spectra and CIE coordinates of Device D2 at different brightness levels. Compared to Device A2, the variation of EL spectra with biases in Device D2 is also reduced. For the brightness of 100 cd/m²-0000 cd/m², Device D2 exhibits smaller shift of CIE coordinates (Δx=−0.043, Δy=−0.008). FIG. 10B shows the external quantum efficiency/power efficiency (in the forward viewing direction) versus current density for Device D2, while FIG. 10C shows the I-V-L characteristics of Device D2. Device D2 has peak efficiencies of 14.9%, 30.7 cd/A, and 21.8 lm/W in the forward viewing direction, corresponding to total peak efficiencies of 25.3% and 37.1 lm/W. And it exhibits efficiencies of 11.5 lm/W, 13.5%, and 27.9 cd/A in the forward viewing direction at the practical brightness of 100 cd/m².

### Example 3

### Construction and Testing of Four OLED Devices

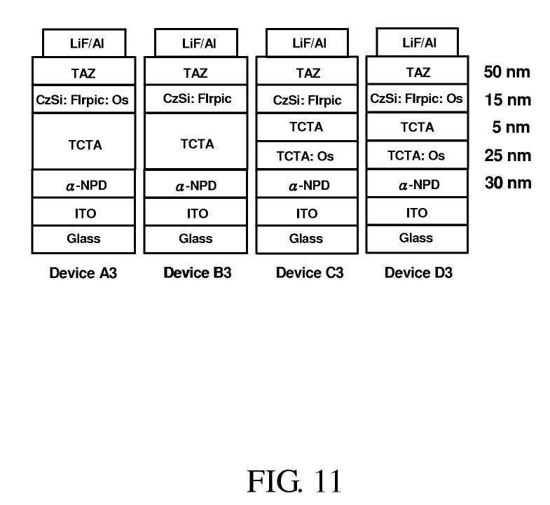

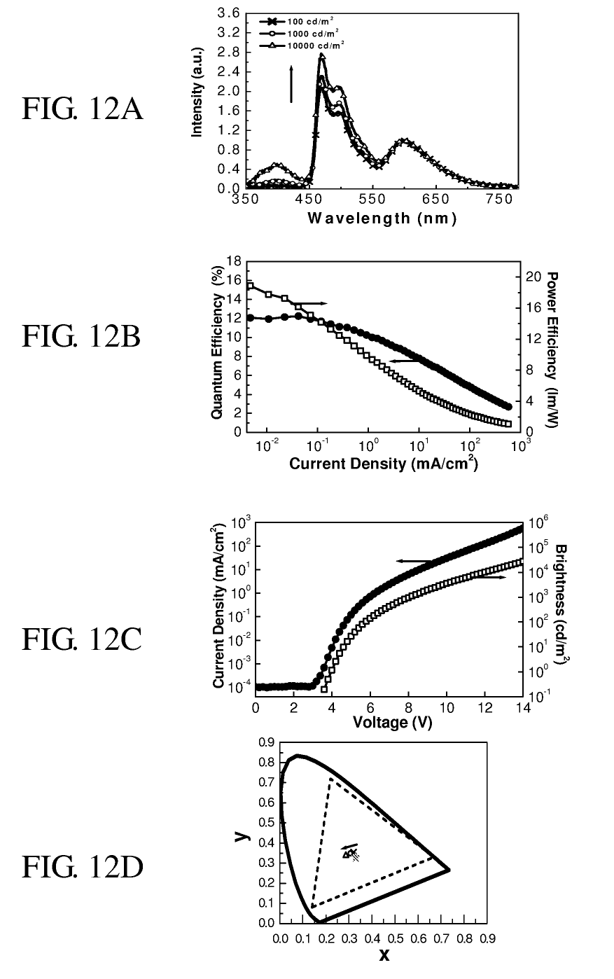

In Example 3, the emitting host material, mCP, was replaced by another wide-gap host material, CzSi. FIG. 11 depicts the schematic structures of devices A3, B3, C3 and D3. As shown in FIG. 11, the structure of Device A3 is: Glass/ITO/α-NPD (30 nm)/TCTA (30 nm)/CzSi: FIrpic 8 wt. %: Os(bpftz)₂(PPh₂Me)₂ 0.5 wt. % (15 nm)/TAZ (50 nm)/LiF (0.5 nm)/Al (150 nm). FIG. 12A shows the normalized EL spectra of Device A3 at different brightness levels, with corresponding CIE coordinates shown in FIG. 12D. From the EL spectra and CIE coordinates, the balanced white emission is obtained by using CzSi as the host material. FIG. 12B shows the external quantum efficiency/power efficiency (in the forward viewing direction) versus current density of Device A3. FIG. 12C shows the I-V-L characteristics of Device A3. FIG. 12D shows the CIE coordinates of Device A3 at different brightness levels. The summarized EL characteristics of Device A3 to D3 are shown in Table 3.

Table 3 is the summary of devices characteristics in example 3.

TABLE 3

| | Max. | Efficiencies | Max. | |
|---|---|---|---|---|
| | Efficiencies | (at 100 cd/m²) | Total | CIE coordinates |
| | [%, cd/A, | [%, cd/A, | efficiencies | (at 10², |
| Device | lm/W] | lm/W] | [%, lm/W] | 10⁴ cd/m² ) |
| A3 | 12.2, 24.2, | 10.8, 20.6, | 20.7, 31.6 | (0.321, 0.353), |
| | 18.6 | 11.1 | | (0.287, 0.337) |
| B3 | 11.2, 23.2, | 9.6, 19.6, | — | (0.166, 0.337), |
| | 18.2 | 10.6 | | (0.167, 0.323) |
| C3 | 12.5, 25.9, | 10.6, 21.8, | — | (0.171, 0.335), |
| | 19.7 | 9.3 | | (0.179, 0.330) |
| D3 | 14.1, 26.6, | 12.2, 23.5, | 24.0, 34.7 | (0.324, 0.355), |
| | 20.4 | 9.7 | | (0.304, 0.346) |

Device A3 exhibits peak efficiencies of 12.2% photon/electron, 24.2 cd/A, and 18.6 lm/W for the forward viewing directions. At the practical brightness of 100 cd/m², the forward viewing efficiencies remain around 10.8%, 20.6 cd/A, and 11.1 lm/W. Furthermore, Device A3 has a total peak external quantum efficiency and a total power efficiency of 20.7% and 31.6 lm/W, respectively. Similarly, its color varies with bias (Δx=−0.034, Δy=−0.016).

The control blue-emitting OLED (Device B3 showed in FIG. 11) in example 3 has the structure of: ITO/α-NPD (30 nm)/TCTA (30 nm)/CzSi: FIrpic 8 wt. % (15 nm)/TAZ (50 nm)/LiF (0.5 nm)/Al (150 nm), which is nearly same as that of Device A3, except for no Os complex co-doped into the mCP host.

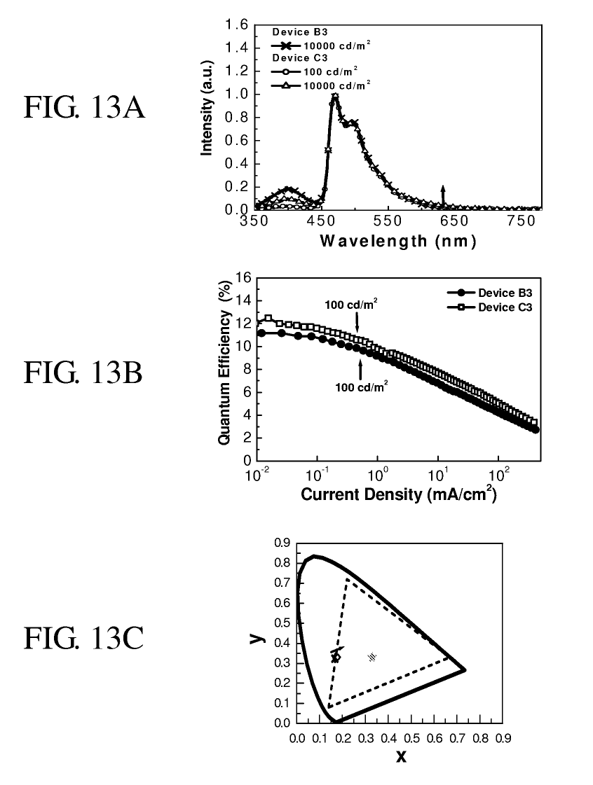

FIG. 13A shows the normalized EL spectra of Device B3 (at 10000 cd/m²) and C3 (at 100 cd/m² and 10000 cd/m²). FIG. 13B shows the external quantum efficiency (in the forward viewing direction) versus current density for Device B3 and C3. FIG. 13C shows the CIE coordinates of Device B3 (at 10000 cd/m²) and C3 (at 100 cd/m² and 10000 cd/m²). In example 3, Device B3 shows better carrier balance and has higher external quantum efficiency of 11.2% (than B1) in the forward viewing directions. (FIG. 13B and Table 3). However, the efficiency of Device B3 remains lower than the efficiency of Device A3. Similarly, we also test the Device C3 in this series. The Os complex was doped into a portion (25 nm) of the hole-transport layer TCTA. This device C3 has the structure of: Glass/ITO/α-NPD (30 nm)/TCTA: Os(bpftz)₂(PPh₂Me)₂ 3.0 wt. % (25 nm)/TCTA (5 nm)/CzSi: FIrpic 8 wt. % (15 nm)/TAZ (50 nm)/LiF (0.5 nm)/Al (150 nm). As shown in FIG. 13A, EL spectra of Device C3 still shows dominant blue emission of FIrpic, yet the peak quantum efficiency is now raised to 12.5% (25.9 cd/A) as compared to the 11.2% observed for Device B3 (shown in FIG. 13B and Table 3).

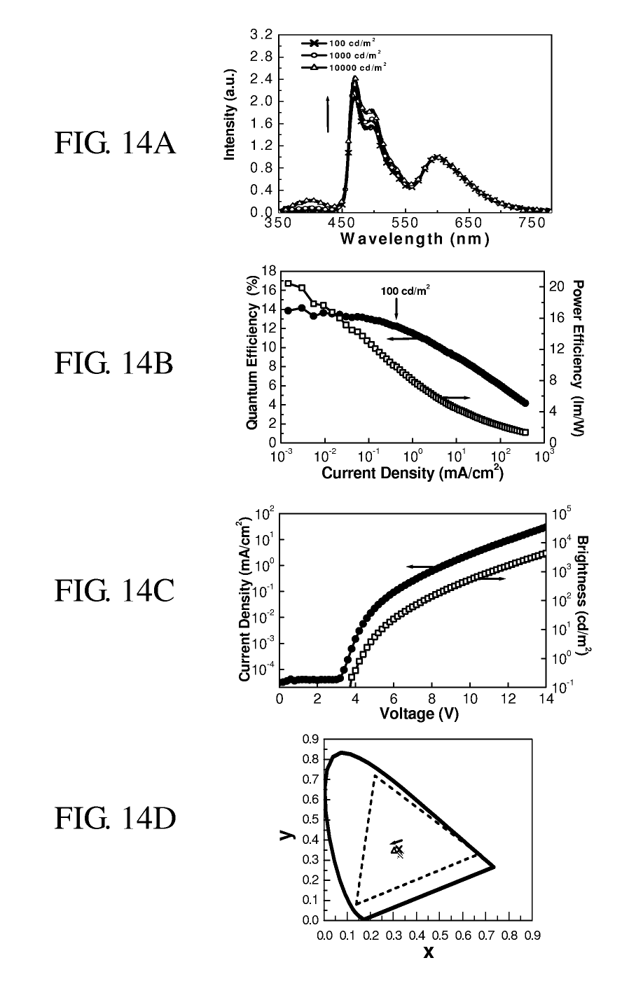

The WOLED D3 with double emitting layers (shown in FIG. 1) was fabricated using the structure of: Glass/ITO/α-NPD (30 nm)/TCTA: Os(bpftz)₂(PPh₂Me)₂ 3.0 wt. % (25 nm)/TCTA (5 nm)/CzSi: FIrpic 8 wt. %: Os(bpftz)₂(PPhMe)₂ 0.2 wt. % (15 nm)/TAZ (50 nm)/LiF (0.5 nm)/Al (150 nm). FIG. 14A and 14D show the normalized EL spectra and CIE coordinates of Device D3 at different brightness levels. Compared to Device A3, the variation of EL spectra with biases in Device D3 is also reduced. For the brightness of 100 cd/m²-10000 cd/m², it exhibits smaller shift of CIE coordinates (Δx=−0.020, Δy=−0.009). FIG. 14B shows the external quantum efficiency/power efficiency (in the forward viewing direction) versus current density for Device D3, while FIG. 14C shows the I-V-L characteristics of Device D3. Device D3 has peak efficiencies of 14.1%, 26.6 cd/A, and 20.4 lm/W in the forward viewing direction, corresponding to total peak efficiencies of 24.0% and 34.7 lm/W. It exhibits efficiencies of 12.2%, 23.5 cd/A and 9.7 lm/W in the forward viewing direction at the practical brightness of 100 cd/m².

We claim:

1. An organic light-emitting device incorporating multifunctional osmium complexes, comprising:
a pair of electrodes;
at least one electron-transport layer, disposed between the pair of electrodes;
at least one hole-transport layer, disposed between the pair of electrodes; and at least one emitting layer, disposed between the electron-transport layer and the hole-transport layer, wherein at least one of the emitting layer(s) is doped with a second phosphorescent complex showing strong emission at the shorter wavelength region of 400˜550 nm, and at least one of the hole-transport layer and the emitting layer is doped with Os complex.

2. The organic light-emitting device according to claim 1, wherein the electrode or the electron-transport layer further comprises an electron-injection layer that is located between the electron-transport layer and the electrode.

3. The organic light-emitting device according to claim 1, wherein the Os complex possesses orange or red emission between 580˜650 nm, and with relatively higher HOMO energy level.

4. The organic light-emitting device according to claim 1, wherein the Os complexes comprise at least one of Os(bpftz)₂(PPh₂Me)₂, Os(fptz)₂(PPh₂Me)₂, Os(fppz)₂(PPh₂Me)₂, Os(bpftz)₂(PPhMe₂)₂, Os(fptz)₂(PPhMe₂)₂, Os(fptz)₂(dppm)₂ and Os(fptz)₂(dppee)₂.

5. The organic light-emitting device according to claim 1, wherein the Os complex is the orange-emitting complex Os(bpftz)₂(PPh₂Me)₂.

6. The organic light-emitting device according to claim 1, wherein the Os complex is replaced by other phosphorescent metal complexes possessing similar orange or red emission in the range 580˜650 nm and with relatively higher HOMO energy level.

7. The organic light-emitting device according to claim 1, wherein the second phosphorescent complex showing strong emission at the shorter wavelength region are green, blue-green or blue-emitting phosphorescent metal complexes, showing emission in the range 400 nm to 550 nm.

8. The organic light-emitting device according to claim 1, wherein the blue-green or blue-emitting phosphorescent metal complexes comprise at least one of FIrpic, FIrtaz, FIrN4, [Ir(dfppy)(pic)₂], FIr6, [Ir(dfppy)(fppz)₂] and [Ir(dfppy)₂(fptz)] and their configurational isomers with emission in the range 400˜500 nm.

9. The organic light-emitting device according to claim 1, wherein the blue-green or blue-emitting phosphorescent metal complexes comprise the blue-green emitting FIrpic.

10. The organic light-emitting device according to claim 1, wherein the emitting layer comprises the host materials: 3-bis(9-carbazolyl)benzene (mCP), p-bis(triphenylsilyly)benzene (UGH2), 3,5-bis(9-carbazolyl)tetraphenylsilane (SimCP), or 9-(4-tertbutylphenyl)-3,6-bis(tri-phenylsilyl)-9H-carbazole (CzSi).

11. The organic light-emitting device according to claim 1, wherein the emitting layer comprises the host 1,3-bis(9-carbazolyl)benzene (mCP).

12. The organic light-emitting device according to claim 1, wherein the hole-transport layer comprises 4,4′-bis[N-(1-naphthyl)-N-phenyl-amino]biphenyl (α-NPD), 4,4′,4″-tris(carbazole-9-yl)-triphenylamine (TCTA), 4,4′,4″-Tris(N,N-diphenyl-amino)triphenylamine (NATA), 4,4′,4″-Tris(N-3-methylphenyl-N-phenyl-amino)triphenylamine (m-MTDATA), N,N,N′,N′-tetrakis(4-methoxy-phenyl)benzidine (MeO-TPD), N,N′-Bis(3-methylphenyl)-N,N′-bis(phenyl)-benzidine (TPD), 2,2′,7,7′-Tetrakis(m,n-diphenylamino)-9,9′-spirobifluorene (spiro-TAD), or 9,9-Bis[4-(N,N-bis-biphenyl-4-yl-amino)phenyl]-9H-fluorene (BPAPF).

13. The organic light-emitting device according to claim 1, wherein the hole-transport layer comprises 4,4′-bis[N-(1-naphthyl)-N-phenyl-amino]biphenyl (α-NPD) or 4,4′,4″-tris(carbazole-9-yl)-triphenylamine (TCTA).

14. The organic light-emitting device according to claim 1, wherein the electron-transport layer comprises 3-(4-biphenylyl)-4-phenyl-5-(4-tert-butylphenyl)-1,2,4-triazole (TAZ), 2,2′,2″-(1,3,5-Benzinetriyl)-tris(1-phenyl-1-H-benzimidazole) (TPBi), 2-(4-Biphenylyl)-5-(4-tert-butylphenyl)-1,3,4-oxadiazole (PBD), 2,9-Dimethyl-4,7-diphenyl-1,10-phenanhroline (BCP), 4,7-Diphenyl-1,10-phenanthroline (BPhen), Bis-(2-methyl-8-quinolinolate)-4-(phenylphenolato)aluminium (BAlq), 1,3-Bis[2-(2,2′-bipyridine-6-yl)-1,3,4-oxadiazo-5-yl]benzene (Bpy-OXD), or 1,3-Bis[5-(4-tert-butylphenyl)-1,3,4-oxadiazole-2-yl]benzene) (OXD-7).

15. The organic light-emitting device according to claim 1, wherein the electron-transport layer comprises 3-(4-biphenylyl)-4-phenyl-5-(4-tert-butylphenyl)-1,2,4-triazole (TAZ).

16. The organic light-emitting device according to claim 1, wherein at least one of the electrodes is made of transparent conducting materials.

17. The organic light-emitting device according to claim 1, wherein the transparent conducting materials comprise optically transparent indium tin oxide (ITO).
